(19) United States
(12) Patent Application Publication
(10) Pub. No.: US 2025/0259788 A1
(43) Pub. Date: Aug. 14, 2025

(54) CAPACITOR, METHOD OF MANUFACTURING THE SAME, AND DEVICE INCLUDING CAPACITOR

(71) Applicant: Seoul National University R&DB foundation, Seoul (KR)

(72) Inventor: Cheol Seong Hwang, Seoul (KR)

(21) Appl. No.: 19/045,670

(22) Filed: Feb. 5, 2025

(30) Foreign Application Priority Data
Feb. 8, 2024 (KR) 10-2024-0019789

(51) Int. Cl. H01G 4/08; H01G 4/008; H01G 4/33

(52) U.S. Cl. CPC H01G 4/085; H01G 4/008; H01G 4/33

(57) ABSTRACT

The present disclosure provides a capacitor including a first electrode, a second electrode disposed spaced apart from the first electrode, a dielectric layer disposed between the first electrode and the second electrode and including strontium titanium oxide, and a buffer layer disposed between the first electrode and the dielectric layer, wherein the buffer layer may include germanium oxide and a germanium material portion, and the germanium material portion may be composed of germanium uncombined with oxygen.

### CROSS-REFERENCE TO RELATED APPLICATION

This application claims priority of Korean Patent Application No. 10-2024-0019789, filed on Feb. 8, 2024, in the KIPO (Korean Intellectual Property Office), the disclosure of which is incorporated herein entirely by reference.

### BACKGROUND OF THE INVENTION

### Field of the Invention

Embodiments of the present disclosure relate to electrical components/elements and devices and related methods including the same, and more particularly, to capacitors, methods for manufacturing the same, and components/devices including capacitors.

### Description of the Related Art

With the recent acceleration of scale-down of memory devices such as dynamic random access memory (DRAM), the development and performance improvement of high dielectric constant materials (i.e., high-k materials) is required to maintain the capacitance of capacitors. Strontium titanate (SrTiO₃) is attracting attention as a next-generation high dielectric material with a bulk permittivity (^{˜}300) that is much larger than that of Zr-based dielectric films (k: about 30 to 40). However, permittivity and bandgap energy typically have a trade-off relationship, and SrTiO₃ has a relatively low bandgap energy of about 3.2 eV, which may be vulnerable to leakage current. To compensate for these issues, electrode materials with a larger work function than the conventionally used TiN electrodes can be considered as electrodes for SrTiO₃.

However, when SrTiO₃ is formed by atomic layer deposition (ALD) on an electrode material with a large work function, the surface of the electrode material may be reduced due to the strong oxygen binding force of Sr and Ti, and Sr and Ti may be excessively adsorbed on the surface of the electrode material. Therefore, overgrowth similar to chemical vapor deposition (CVD) may occur at the beginning of the deposition. In addition, due to difficulties in controlling the initial deposition rate, it is difficult to deposit strontium titanate thin films with stoichiometric compositions, poorly removed ligands may be retained in the film, and the formation of low-density films may increase the instability of the film, such as increasing the shrinkage rate of the film during post-heat treatment, which increases the possibility of forming leakage current paths.

Strontium titanate deposited at relatively low temperatures is amorphous and requires high-temperature post-heat treatment to form the crystalline phase, and the high-temperature post-heat treatment causes the thin film to shrink in volume/thickness, resulting in defects such as nano-cracks and voids. These defects act as a pathway for leakage current at the junction with the top and bottom electrodes, causing the problem that the minimum leakage current requirements for DRAM capacitors cannot be met. To improve this problem, a two-step process can be used. The two-step process involves first depositing a thin seed SrTiO₃ layer, annealing it to crystallize, and then depositing a main SrTiO₃ layer on top of it, which may allow the formation of the crystalline phase without the need for a high-temperature post-annealing treatment for the main SrTiO₃ layer. However, even in the two-step process, there are limitations and difficulties in the application of DRAM capacitors, such as the high temperature heat treatment required to form the seed layer and the increased complexity of the dielectric film process.

### SUMMARY OF THE INVENTION

The present disclosure aims to provide a capacitor and a method of manufacturing a capacitor that can reduce leakage current while having high capacitance characteristics.

Furthermore, a technical objective of the present invention is to provide a capacitor and a manufacturing method thereof that can improve electrical properties by suppressing the phenomenon of over-deposition (over-growth) of the dielectric layer and promoting low-temperature crystallization.

Furthermore, a technical objective of the present invention is to provide a capacitor and a manufacturing method thereof that can reduce the thermal budget and thermal process burden by reducing the heat treatment temperature and simplify the dielectric layer formation process.

Furthermore, the technical challenge of the present invention is to provide a device comprising the aforementioned capacitors.

The problems that the present invention is intended to solve are not limited to those mentioned above, and other problems not mentioned will be understood by those skilled in the art from the following description.

According to one embodiment of the present invention, there is provided a capacitor comprising: a first electrode; a second electrode disposed spaced apart from the first electrode; a dielectric layer disposed between the first electrode and the second electrode, comprising strontium titanium oxide; and a buffer layer disposed between the first electrode and the dielectric layer, comprising germanium oxide and a germanium material portion, the germanium material portion comprising germanium uncombined with oxygen.

The germanium oxide may be GeOₓ (wherein x is 0<x≤2).

The content of the germanium material portion in the buffer layer may be less than about 50 wt %.

The buffer layer may have a thickness in the range of about 0.2 nm to 3 nm.

The strontium titanium oxide may be SrₓTi₁₋ₓO_{3-y} (wherein x is 0.45≤x≤0.55 and y is 0≤y≤0.5).

The oxygen vacancy concentration of the strontium titanate oxide may be equal to or less than 20 mol %.

The dielectric layer may have a thickness in the range of about 1 nm to 30 nm.

The first electrode may comprise at least one of Ru and RuOₓ (wherein x is 0<x≤2).

The second electrode may comprise at least one of RuOₓ (wherein x is 0<x≤2), Ru, Pt, and TiN.

According to another embodiment of the present invention, there is provided a memory element comprising the aforementioned capacitor as a data storage member.

The memory device may be a dynamic random access memory (DRAM).

According to another embodiment of the present invention, the method comprises: preparing a first electrode; forming a buffer layer comprising germanium oxide using a first atomic layer deposition (ALD) process on the first electrode; forming a dielectric layer comprising strontium titanate oxide using a second ALD process on the buffer layer; and forming a second electrode on the dielectric layer, wherein the buffer layer and the dielectric layer are heat treated by a heat treatment process, and after the heat treatment process, wherein the buffer layer comprises a germanium oxide and a germanium material portion, the germanium material portion comprising germanium uncombined with oxygen. A method of manufacturing a capacitor is provided.

The first ALD process may comprise: supplying a Ge precursor to a chamber in which the first electrode is disposed; purging the chamber with a first purge gas; supplying a first reactant to the chamber; and purging the chamber with a second purge gas.

The second ALD process may include a first sub-cycle and a second sub-cycle.

The first sub-cycle may comprise the steps of supplying a Ti precursor within a chamber in which the first electrode with the buffer layer formed is disposed; purging the chamber with a third purge gas; supplying a second reactant within the chamber; and purging the chamber with a fourth purge gas.

The second sub-cycle may include the steps of feeding Sr precursor into the chamber; purging the chamber with a fifth purge gas; feeding a third reactant into the chamber; and purging the chamber with a sixth purge gas.

In each of the step of forming the buffer layer and the step of forming the dielectric layer, the deposition temperature may be in the range of about 230 to 370° C.

The heat treatment process can be performed at a temperature of about 450-700° C.

After the heat treatment process, the germanium oxide contained in the buffer layer may be GeOₓ (wherein x is 0<x≤2), and the content of the germanium material portion in the buffer layer may be less than about 50 wt %.

After the heat treatment process, the oxygen vacancy concentration of the strontium titanium oxide may be about 20 mol % or less.

The first electrode may comprise at least one of Ru and RuOₓ (wherein x is 0<x≤2).

The second electrode may comprise at least one of RuOₓ (wherein x is 0<x≤2), Ru, Pt, and TiN.

According to embodiments of the present invention, a capacitor and a method of manufacturing the same can be implemented that can reduce leakage current while having high capacitance characteristics. Further, embodiments of the present disclosure enable capacitors and methods of manufacturing the same that can improve electrical properties by suppressing over-deposition (over-growth) of dielectric layers and promoting low-temperature crystallization. Furthermore, according to embodiments of the present invention, capacitors and methods of manufacturing the same can be implemented that can reduce the thermal budget and thermal process burden by reducing the heat treatment temperature and simplify the dielectric layer formation process.

In particular, according to embodiments of the present invention, by inserting a predetermined buffer layer between the first electrode and the dielectric layer, the CVD-like (i.e., CVD-like) overgrowth of the strontium titanium oxide in the dielectric layer can be effectively suppressed at the beginning of the deposition. Furthermore, as the buffer layer promotes the early stage of nucleation of strontium titanium oxide, crystallization can be achieved at a relatively low temperature, and the leakage current density versus equivalent oxide thickness characteristics, i.e., J-EOT characteristics, can be improved. By reducing the complexity of the dielectric layer formation process, the application of strontium titanium oxide as a DRAM capacitor can be improved by using a one-step process based on an in-situ process rather than a conventional two-step process. Furthermore, by reducing the heat treatment temperature, the thermal cost and thermal process burden of the DRAM capacitor process can be reduced.

The capacitors according to embodiments of the present invention can be usefully applied to various devices. In particular, the capacitor according to an embodiment of the present invention may be applied to a semiconductor device, for example, a memory device such as a DRAM, in which case it may be advantageous to improve the integration and performance of the memory device.

However, the effects of the present invention are not limited to the above effects, and may be extended in various ways without departing from the technical ideas and scope of the present invention.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a capacitor according to one embodiment of the present invention.

FIGS. 2A through 2E illustrates cross sectional views of a method of fabricating a capacitor according to one embodiment of the present invention.

FIG. 3 is an exemplary perspective view of a capacitor (sample structure) fabricated in accordance with one embodiment of the present invention.

FIG. 4 illustrates an ALD process sequence that can be applied to a method of manufacturing a capacitor according to one embodiment of the present invention.

FIG. 5 illustrates a Ge precursor that may be applied in a method of manufacturing a capacitor according to one embodiment of the present invention.

FIG. 6 illustrates a Ti precursor that may be applied in a method of manufacturing a capacitor according to one embodiment of the present invention.

FIG. 7 illustrates an exemplary Sr precursor that may be applied in a method of manufacturing a capacitor according to one embodiment of the present invention.

FIG. 8A and FIG. 8B show the results of an X-ray photoelectron spectroscopy (XPS) analysis of a buffer layer formed in a manufacturing method of a capacitor according to one embodiment of the present invention.

FIG. 9A and FIG. 9B show the results of XPS analysis of the dielectric layer formed in the capacitor fabrication method according to the comparison.

FIG. 10A and FIG. 10B show the results of an XPS analysis of a dielectric layer formed in a manufacturing method of a capacitor according to one embodiment of the present invention.

FIG. 11 shows the variation of the layer density of Sr and Ti in the STO layer as a function of the number of ALD cycles of GeOₓ corresponding to the buffer layer, for a fixed number of strontium titanium oxide (STO) cycles, in a method of fabricating a capacitor according to one embodiment of the present invention.

FIG. 12 shows the variation of the layer density of Sr and Ti in the STO layer as a function of the thickness of the GeOₓ layer corresponding to the buffer layer, for a fixed number of strontium titanium oxide (STO) cycles, in a method of manufacturing a capacitor according to one embodiment of the present invention.

FIG. 13 illustrates the variation of the layer density of Sr and Ti in the STO layer as a function of the number of supercycles of strontium titanium oxide (STO) in the fabrication method of the capacitor according to an embodiment and a comparative example of the present invention.

FIG. 14A, FIG. 14B, and FIG. 14C show grazing incident X-ray diffraction (GIXRD) analysis graphs showing the crystallization behavior of the dielectric layer as a function of the post-heat treatment temperature of the dielectric layer according to embodiments and comparative examples of the present invention.

FIG. 15 illustrates an atomic force microscope (AFM) analysis image of a dielectric layer in accordance with embodiments and comparative examples of the present disclosure.

FIG. 16 is a high resolution transmission electron microscope (HRTEM) image showing a cross section of a dielectric layer in accordance with embodiments and comparative examples of the present invention.

FIG. 17 is a scanning electron microscope (SEM) image showing the surface of a dielectric layer according to embodiments and comparative examples of the present invention.

FIG. 18 shows the grain size distribution of a dielectric layer according to embodiments and comparative examples of the present invention.

FIG. 19 shows the results of a GIXRD analysis of a dielectric layer according to embodiments and comparative examples of the present invention.

FIG. 20 is an HRTEM image showing a cross-section of a dielectric layer according to an embodiment and comparative example of the present invention.

FIG. 21 shows the variation of equivalent oxide thickness (tₒₓ) as a function of physical oxide thickness (t_{phy}) for dielectric layers fabricated according to embodiments and comparative examples of the present invention.

FIG. 22 shows the variation of leakage current density with equivalent oxide thickness (EOT) of a dielectric layer fabricated in accordance with embodiments and comparative examples of the present disclosure.

FIG. 23 shows the variation of leakage current density with equivalent oxide thickness (EOT) of dielectric layers fabricated according to embodiments and comparative examples of the present invention.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

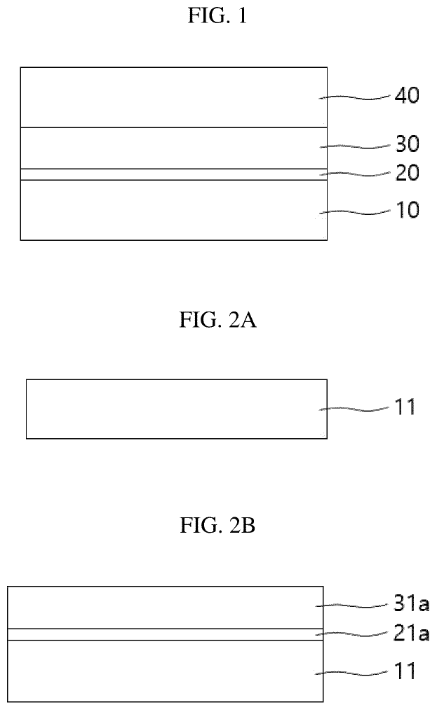

FIG. 1 illustrates a cross-sectional view of a capacitor according to one embodiment of the present invention.

Referring to FIG. 1, a capacitor according to one embodiment of the present invention may include a first electrode 10, a second electrode 40 disposed spaced apart from the first electrode 10, a dielectric layer 30 disposed between the first electrode 10 and the second electrode 40, and a buffer layer 20 disposed between the first electrode 10 and the dielectric layer 30. The dielectric layer 30 may comprise strontium titanium oxide. The dielectric layer 30 may be formed from the strontium titanium oxide. In this case, the dielectric layer 30 may be a strontium titanium oxide layer. The buffer layer 20 may comprise a germanium oxide and a germanium material portion. The germanium material portion may comprise germanium (Ge) uncombined with oxygen. The germanium material portion may be a Ge metal region. The germanium material portion may be a metallic region composed of a plurality of Ge atoms. The first electrode 10 may be a bottom electrode, and the second electrode 40 may be a top electrode. A buffer layer 20 may be contacted on a top surface of the first electrode 10. A dielectric layer 30 may be contacted on the upper surface of the buffer layer 20. A second electrode 40 may be contacted on the upper surface of the dielectric layer 30. The buffer layer 20 may be disposed between the first electrode 10 and the dielectric layer 30, and the dielectric layer 30 may be disposed between the buffer layer 20 and the second electrode 40.

The buffer layer 20 may serve to inhibit over-deposition (over-growth) of the dielectric layer 30 and facilitate low-temperature crystallization during the capacitor manufacturing process. The buffer layer 20 may play a role in improving the crystallization characteristics of the dielectric layer 30. In this regard, the dielectric layer 30 may have low leakage current characteristics. Further, the dielectric layer 30 may have good film quality, may have thin film stability, and may have good electrical properties. Furthermore, the buffer layer 20 can play a role in reducing the thermal cost and thermal process burden in the manufacturing process of the capacitor by reducing the heat treatment temperature. The buffer layer 20 may exhibit the above effects by including the germanium oxide and the germanium material portion.

The germanium oxide included in the buffer layer 20 may be GeOₓ, wherein x may satisfy 0<x≤2. The content of the germanium material portion in the buffer layer 20 may be, for example, less than about 50 wt %. The remaining portion of the buffer layer 20 excluding the germanium material portion may comprise the germanium oxide. Thus, the content of the germanium oxide in the buffer layer 20 may be, for example, about 50 wt % or more.

According to one embodiment, the buffer layer 20 may have a thickness in the range of about 0.2 nm to 3 nm. If the thickness of the buffer layer 20 is less than about 0.2 nm, the effect provided by the buffer layer 20 may not be sufficient. On the other hand, if the thickness of the buffer layer 20 is excessively thick, the buffer layer 20 may have a lower permittivity than the dielectric layer 30, which may adversely affect the characteristics of the capacitor. For this reason, the buffer layer 20 may have a thickness in the range of about 0.2 nm to 3 nm. However, the thickness range of the buffer layer 20 is not limited to the foregoing, and may vary in some cases.

The dielectric layer 30 may comprise strontium titanium oxide, wherein the strontium titanium oxide may have a crystalline structure. The strontium titanium oxide may have a perovskite crystal structure. The strontium titanium oxide may have a polycrystalline structure. The dielectric layer 30 may have a high dielectric constant. As a non-limiting example, the dielectric layer 30 may have a permittivity of about 90 to 300. Further, the dielectric layer 30 can have a good film quality and can have good electrical properties. The dielectric layer 30 may have a high permittivity and yet have low leakage current characteristics. The dielectric layer 30 may have a small equivalent oxide thickness (EOT).

According to one embodiment, the strontium titanium oxide may be Srₓ Ti₁₋ₓ O_{3-y}, wherein x may satisfy 0.455≤x≤0.55, and y may satisfy 0≤y≤0.5. Meanwhile, the strontium titanium oxide may have an oxygen vacancy concentration of, for example, about 20 mol % or less. The lower the oxygen vacancy concentration, the better the crystalline properties of the strontium titanium oxide may be, and the better the dielectric properties and electrical properties may be. However, the oxygen vacancy concentration of the strontium titanium oxide is not limited to the foregoing, and may vary in some cases. The thickness (physical thickness) of the dielectric layer 30 may be, as a non-limiting example, from about 1 nm to 30 nm or from about 3 nm to 25 nm. When the dielectric layer 30 has a suitable thickness, it may be advantageous to have good dielectric and electrical properties.

According to one embodiment, the first electrode 10 may comprise a conductive material (metal or metallic material) having a large work function. For example, the first electrode 10 may comprise a conductive material having a larger work function than TiN. As a specific example, the first electrode 10 may include at least one of Ru and RuOₓ (where x is 0<x≤2). If the first electrode 10 includes a Ru electrode, RuOₓ (wherein x is 0<x≤2) may be present on a surface portion of the Ru electrode. The first electrode 10 may be a Ru electrode or a RuOₓ electrode, or an electrode comprising Ru and RuOₓ. However, the specific material of the first electrode 10 is not limited to the foregoing. If the first electrode 10 comprises a conductive material with a large work function, it may be advantageous to improve the leakage current characteristics of the capacitor.

According to one embodiment, the second electrode 40 may comprise a conductive material (metal or metallic material) having the same or similar work function as TiN or having a work function greater than TiN. As a specific example, the second electrode 40 can include at least one of RuOₓ (where x is 0<x≤2), Ru, Pt, and TiN. In one example, the second electrode 40 may be a RuO₂ electrode or may include RuO₂. The second electrode 40 may have a monolayer structure or may have a multilayer structure. However, the specific material of the second electrode 40 is not limited to the foregoing. If the second electrode 40 comprises a conductive material having a large work function or a suitable work function, it may be advantageous to improve the leakage current characteristics of the capacitor.

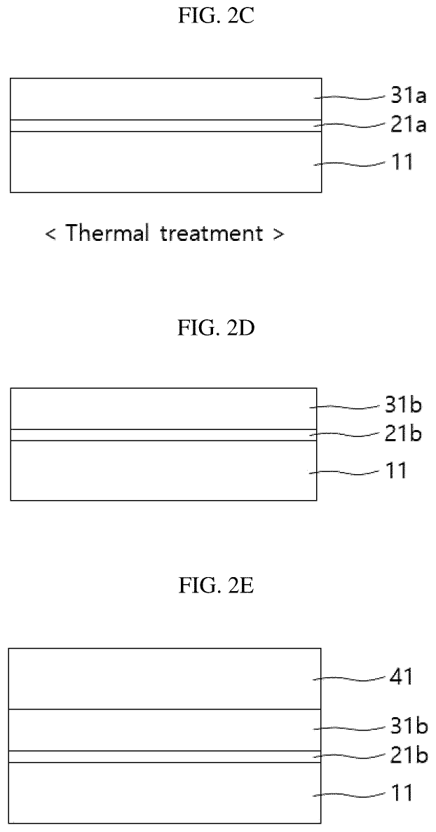

FIGS. 2A through 2E illustrates cross-sectional views of a method of fabricating a capacitor according to one embodiment of the present invention.

Referring to FIG. 2A, a first electrode 11 may be provided. The first electrode 11 may be a bottom electrode. The first electrode 11 may be deposited on a predetermined substrate or substructure by sputtering or atomic layer deposition (ALD). However, the method of forming the first electrode 11 is not limited to the foregoing. The first electrode 11 may comprise a conductive material (metal or metallic material) having a large work function. For example, the first electrode 11 may comprise a conductive material having a larger work function than TiN. As a specific example, the first electrode 11 may include at least one of Ru and RuOₓ (where x is 0<x≤2). If the first electrode 11 comprises a Ru electrode, RuOₓ (wherein x is 0<x≤2) may be present on a surface portion of the Ru electrode. The first electrode 11 may be a Ru electrode or a RuOₓ electrode, or an electrode comprising Ru and RuOₓ. However, the specific material of the first electrode 11 is not limited to the foregoing.

Referring to FIG. 2B, a buffer layer 21a comprising germanium oxide can be formed on the first electrode 11 using a first ALD process. Then, on the buffer layer 21a, a dielectric layer 31a comprising strontium titanate oxide can be formed using a second ALD process. The step of forming the buffer layer 21a and the step of forming the dielectric layer 31a may be performed back-to-back as an in-situ process in a single chamber.

Prior to forming the dielectric layer 31a, the buffer layer 21a may be composed of germanium oxide, or may include germanium oxide as a major constituent material. For example, prior to forming the dielectric layer 31a, the buffer layer 21a may be a germanium oxide layer. In some cases, during the process of depositing the dielectric layer 31a, a portion of the germanium oxide in the buffer layer 21a may be transformed into a germanium material part, i.e., during the process of depositing the dielectric layer 31a, a portion of the germanium oxide may be reduced to become a germanium material part. The germanium material portion may correspond to a metallic region. Thus, after deposition of the dielectric layer 31a, the buffer layer 21a may include a germanium oxide and a germanium material part.

The buffer layer 21a may play a role in suppressing the phenomenon of over-deposition (over-growth) of the dielectric layer 31a and promoting low-temperature crystallization in the manufacturing process of the capacitor. The buffer layer 21a may play a role in improving the crystallization characteristics of the dielectric layer 31a. In this regard, the dielectric layer that the capacitor finally includes (the final dielectric layer) may have a low leakage current characteristic. Further, the final dielectric layer may have good film quality, may have thin film stability, and may have good electrical properties. Furthermore, the buffer layer 21a may play a role in reducing the heat treatment temperature in the manufacturing process of the capacitor, thereby reducing the thermal cost and the burden of the thermal process.

According to one embodiment, the first ALD process may comprise the steps of supplying a Ge precursor to a chamber in which the first electrode 11 is disposed, purging the chamber with a first purge gas, supplying a first reactant to the chamber, and purging the chamber with a second purge gas. The first reactant may be a source of oxygen. If the first electrode 11 is a Ru electrode, a RuOₓ layer may be present on the surface of the Ru electrode as a native oxide film. Further, a RuOₓ layer may also be formed on the surface of the Ru electrode by the first reactant supplied at the beginning of the first ALD process to form the buffer layer 21a. In the first ALD process, the deposition of the Ge precursor from the RuOₓ layer may initially take place at a relatively high rate of about 2 to 2.5 Å/cycle due to the deprivation of oxygen by the Ge precursor, and the high surface energy of the first electrode 11 may enable two-dimensional thin film growth. For reference, the formation energy (oxide formation energy) of RuO₂ may be −201 kJ/mol, and the formation energy (oxide formation energy) of GeO₂ may be −521 kJ/mol at 600K.

According to one embodiment, the first ALD process can be performed using a Ge precursor comprising an amine group. The Ge precursor may comprise N atoms bonded to Ge atoms. As a non-limiting example, the Ge precursor may be Ge(NMePh)(NMe₂)₃. The Ge precursor may have high thermal stability as a precursor including an amine group, and may have high affinity with the material of the first electrode 11 (e.g., Ru, etc.) because it includes a Ge atom and an N atom having a non-covalent electron pair within one molecular structure. According to an embodiment of the present invention, it may be possible to form a flat and well-coverage GeOₓ layer with only an initial one cycle in the first ALD process. However, the specific material of the Ge precursor is not limited to the foregoing, and may vary from case to case.

According to one embodiment, the second ALD process may comprise a first sub-cycle and a second sub-cycle. The first sub-cycle may include supplying a Ti precursor into a chamber in which the first electrode 11 with the buffer layer 21a formed is disposed, purging the chamber with a third purge gas, supplying a second reactant into the chamber, and purging the chamber with a fourth purge gas. Wherein, the second reactant may be a source of oxygen. The second sub-cycle may include supplying an Sr precursor within the chamber, purging the chamber with a fifth purge gas, supplying a third reactant within the chamber, and purging the chamber with a sixth purge gas. Wherein, the third reactant may be a source of oxygen. The first sub-cycle may be performed one or more times, and the second sub-cycle may be performed one or more times. The first sub-cycle and the second sub-cycle may comprise a super-cycle, wherein the super-cycle may be performed one or more times.

According to one embodiment, the second ALD process can be performed using a Cp (cyclopentadienyl)-based Sr precursor and a Cp-based Ti precursor. As a non-limiting example, the Sr precursor may be Sr(iPr₃Cp)₂ and the Ti precursor may be Ti(Me₅Cp)(OMe)₃. When a Cp-based Sr precursor and a Cp-based Ti precursor are used, the thin film properties of the dielectric layer 31a may be improved at a deposition temperature of about 230° C. or higher. When deposition is performed at a lower temperature than about 230° C., carbon or other ligands may be generated or retained, which may result in a decrease in the thin film properties. In this respect, it may be preferable to use a Cp-based Sr precursor and a Cp-based Ti precursor. However, the types of Sr precursors and Ti precursors are not limited to the foregoing, and may vary in some cases. Other types of Sr/Ti precursors other than those of the Cp series may also be used.

According to one embodiment, in each of the step of forming the buffer layer 21a and the step of forming the dielectric layer 31a, the deposition temperature may be in the range of about 230 to 370° C. The deposition temperature may be a temperature of the substrate. The buffer layer 21a and the dielectric layer 31a can be deposited at a relatively low temperature of less than about 400° C. At this time, the dielectric layer 31a may be amorphous or may include an amorphous phase. Meanwhile, the process pressure in each of the step of forming the buffer layer 21a and the step of forming the dielectric layer 31a may be, for example, about 0.1 torr to 5 torr, but is not limited thereto.

According to one embodiment, the buffer layer 21a may have a thickness in the range of about 0.2 nm to 3 nm. If the thickness of the buffer layer 21a is less than about 0.2 nm, the effect provided by the buffer layer 20 may not be sufficient. If the thickness of the buffer layer 21a is excessively thick, it may adversely affect the dielectric properties of the capacitor. For this reason, the buffer layer 21a may have a thickness in the range of about 0.2 nm to 3 nm. However, the thickness range of the buffer layer 21a is not limited to the foregoing, and may vary in some cases. Meanwhile, the thickness of the dielectric layer 31a may be in the range of about 1 nm to 30 nm or about 3 nm to 25 nm, as non-limiting examples.

According to one embodiment, in the step of forming the buffer layer 21a and the step of forming the dielectric layer 31a, the precursor may be injected into the chamber by, for example, a bubbler type source injection. Further, the chamber may be, for example, a traveler type chamber. However, the injection method of the precursor and the type of chamber may be varied.

Referring to FIG. 2C, a heat treatment process may be performed on the buffer layer 21A and the dielectric layer 31A. The heat treatment process may be referred to as a post-heat treatment process. Further, the heat treatment process may be referred to as post-deposition annealing (PDA). Through the heat treatment process, the dielectric layer 31a can be crystallized. According to one embodiment, the heat treatment process can be performed at a temperature in the range of about 450 to 700° C. The heat treatment process may be performed in a rapid thermal annealing (RTA) method. The heat treatment process can be performed in an N2 atmosphere, and can be performed at a pressure condition of tens of torr to hundreds of torr (in a non-limiting example, about 110 torr) for tens of seconds to tens of minutes (in a non-limiting example, about 2 minutes). However, the specific conditions of the heat treatment process are not limited to the foregoing, and may vary from case to case. The result of performing the above heat treatment process is shown in FIG. 2D.

Referring to FIG. 2D, the buffer layer after the heat treatment process is denoted by reference numeral 21B, and the dielectric layer after the heat treatment process is denoted by reference numeral 31B. After the heat treatment process, the buffer layer 21B may include a germanium oxide and a germanium material portion. The germanium material portion may comprise germanium (Ge) uncombined with oxygen. The germanium material portion may be a Ge metal region. The germanium material portion may be a metallic region composed of a plurality of Ge atoms. The germanium material portion may result from the process of depositing the dielectric layer 31a in FIG. 2B and the process of heat treating the buffer layer 21b and the dielectric layer 31a in FIG. 2C.

According to one embodiment, the germanium oxide included in the buffer layer 21b may be GeOₓ, wherein x may satisfy 0<x≤2. The content of the germanium material portion in the buffer layer 21b may be, for example, less than about 50 wt %. The remaining portion of the buffer layer 21b excluding the germanium material portion may comprise the germanium oxide. Thus, the content of the germanium oxide in the buffer layer 21b may be, for example, about 50 wt % or more.

The dielectric layer 31b may comprise strontium titanium oxide, wherein the strontium titanium oxide may have a crystalline structure. The strontium titanium oxide may have a perovskite crystal structure. The strontium titanium oxide may have a polycrystalline structure. The dielectric layer 31b may have a high dielectric constant. As a non-limiting example, the dielectric layer 31b may have a permittivity of about 90 to 300. Further, the dielectric layer 31b can have a good film quality and can have good electrical properties. The dielectric layer 31b may have a high permittivity and yet have low leakage current characteristics. The dielectric layer 31b may have a small equivalent oxide thickness (EOT).

According to one embodiment, the strontium titanium oxide may be SrₓTi₁₋ₓO_{3-y}, wherein x may satisfy 0.455≤x≤0.55, and y may satisfy 0≤y≤0.5. Meanwhile, the strontium titanium oxide may have an oxygen vacancy concentration of, for example, about 20 mol % or less. The lower the oxygen vacancy concentration, the better the crystalline properties of the strontium titanium oxide may be, and the better the dielectric properties and electrical properties may be. However, the oxygen vacancy concentration of the strontium titanium oxide is not limited to the foregoing, and may vary in some cases.

Referring to FIG. 2E, a second electrode 41 may be formed on the dielectric layer 31b. The second electrode 41 may be a top electrode. The second electrode 41 may be deposited by sputtering or other various other deposition methods. The second electrode 41 may comprise a conductive material (metal or metallic material) having the same or similar work function as TiN, or having a work function greater than TiN. As a specific example, the second electrode 41 can include at least one of RuOₓ (where x is 0<x≤2), Ru, Pt, and TiN. In one example, the second electrode 41 may be a RuO₂ electrode or may include RuO₂. The second electrode 41 may have a monolayer structure or may have a multilayer structure. However, the specific material of the second electrode 41 is not limited to the foregoing.

While the manufacturing method described with reference to FIGS. 2A through 2E illustrates and describes performing the heat treatment (post-annealing) process prior to forming the second electrode 41, in other embodiments, the heat treatment process may be performed after forming the second electrode 41.

According to embodiments of the present invention, a capacitor and a method of manufacturing the same can be implemented that can reduce leakage current while having high capacitance characteristics. Further, embodiments of the present disclosure enable capacitors and methods of manufacturing the same that can improve electrical properties by suppressing over-deposition (over-growth) of dielectric layers and promoting low-temperature crystallization. Furthermore, according to embodiments of the present invention, capacitors and methods of manufacturing the same can be implemented that can reduce the thermal budget and thermal process burden by reducing the heat treatment temperature and simplify the dielectric layer formation process.

In particular, according to embodiments of the present invention, by inserting a predetermined buffer layer between the first electrode and the dielectric layer, CVD-like (i.e., CVD-like) overgrowth in the early stages of depositing strontium titanium oxide on the dielectric layer can be effectively suppressed. Furthermore, as the buffer layer promotes the early stage of nucleation of strontium titanium oxide, crystallization can be achieved at a relatively low temperature, and the leakage current density versus equivalent oxide thickness characteristics, i.e., J-EOT characteristics, can be improved. By reducing the complexity of the dielectric layer formation process, the application of strontium titanium oxide as a DRAM capacitor can be improved by using a one-step process based on an in-situ process rather than a conventional two-step process. Furthermore, by reducing the heat treatment temperature, the thermal cost and thermal process burden of the DRAM capacitor process can be reduced.

In a two-step process, a thin seed dielectric layer is first deposited, heat treated to crystallize it, and then the main dielectric layer is deposited on top of it. In this case, the deposition process must be divided into two steps, as the seed dielectric layer is deposited, the heat treatment process is performed on the seed layer, and the main dielectric layer is deposited. In addition, even in the two-step process, there are limitations and difficulties in the application of DRAM capacitors, such as the high temperature heat treatment required to form the seed layer and the increased complexity of the dielectric film process. However, in an embodiment of the present invention, the buffer layer and dielectric layer can be continuously deposited in an in-situ manner without a seed layer, and a relatively low-temperature heat treatment process can be performed on them. Thus, according to embodiments of the present invention, the complexity of the dielectric layer formation process is reduced, the thermal process burden is reduced, and it is easy to obtain excellent electrical properties, which may increase the applicability of strontium titanium oxide as a DRAM capacitor.

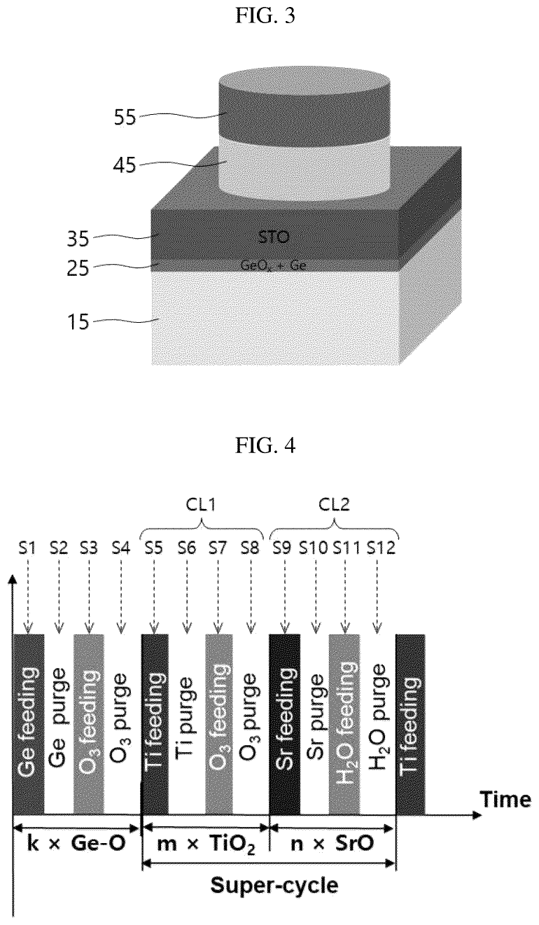

FIG. 3 is an exemplary perspective view of a capacitor (sample structure) fabricated in accordance with one embodiment of the present invention.

Referring to FIG. 3, a capacitor according to an embodiment of the present invention may include a first electrode 15, a buffer layer 25 disposed on the first electrode 15, a dielectric layer 35 disposed on the buffer layer 25, and a second electrode 45 disposed on the dielectric layer 35. The materials and features of each of the first electrode 15, the buffer layer 25, the dielectric layer 35, and the second electrode 45 may correspond to the materials and features of the first electrode 10, the buffer layer 20, the dielectric layer 30, and the second electrode 40 described in FIG. 1. Additionally, a contact electrode 55 may be further disposed on the second electrode 45. As a non-limiting example, the contact electrode 55 may comprise Pt or other precious metal material. The second electrode 45 and the contact electrode 55 may be considered to comprise a single “second electrode” or “top electrode”. The second electrode 45 and the contact electrode 55 may have a dot pattern shape, for example, but not limited to. The structure of the capacitor illustrated in FIG. 3 is only a sample structure, and the structure of the capacitor according to embodiments may vary.

FIG. 4 is a graph illustrating an ALD process sequence that can be applied to a method of manufacturing a capacitor according to one embodiment of the present invention.

Referring to FIG. 4, a first ALD process can be utilized to form a buffer layer comprising germanium oxide. Then, on the buffer layer, a dielectric layer comprising strontium titanate oxide can be formed using a second ALD process.

The first ALD process may comprise a first step (S1) of supplying a Ge precursor to a chamber in which a first electrode is disposed, a second step (S2) of purging the chamber with a first purge gas, a third step (S3) of supplying a first reactant to the chamber, and a fourth step (S4) of purging the chamber with a second purge gas. The first reactant may be a source of oxygen. The first reactant may be, for example, ozone (O₃) or may include ozone (O₃), but is not limited to. The first to fourth steps (S1 to S4) may be performed one or more times. In FIG. 4, the first to fourth steps S1 to S4 are illustrated as being performed k times.

The second ALD process may comprise a first sub-cycle (CL1) and a second sub-cycle (CL2). The first sub-cycle (CL1) may include a fifth step (S5) of supplying a Ti precursor into the chamber in which a first electrode with a buffer layer formed is disposed, a sixth step (S6) of purging the chamber with a third purge gas, a seventh step (S7) of supplying a second reactant into the chamber, and an eighth step (S8) of purging the chamber with a fourth purge gas. Here, the second reactant may be a source of oxygen. The second reactant may be, for example, but not limited to, ozone (03) or may include ozone (03). The fifth through eighth steps (S5 through S8) may be performed one or more times. In FIG. 4, the fifth through eighth steps (S5 through S8) are illustrated as being performed m times. Here, m may be, for example, five days, but is not limited thereto.

The second sub-cycle (CL2) may comprise a ninth step (S9) of supplying Sr precursor into the chamber, a tenth step (S10) of purging the chamber with a fifth purge gas, an eleventh step (S11) of supplying a third reactant into the chamber, and a twelfth step (S12) of purging the chamber with a sixth purge gas. Here, the third reactant may be a source of oxygen. The third reactant may comprise, for example, but not limited to, H₂O or H₂O. Steps S9 through S12 may be performed one or more times. In FIG. 4, the ninth through twelfth steps (S9 through S12) are illustrated as being performed n times. Here, n may be, for example, one, but is not limited to one. The first sub-cycle CL1 and the second sub-cycle CL2 may comprise a super-cycle, and the super-cycle may be performed more than once.

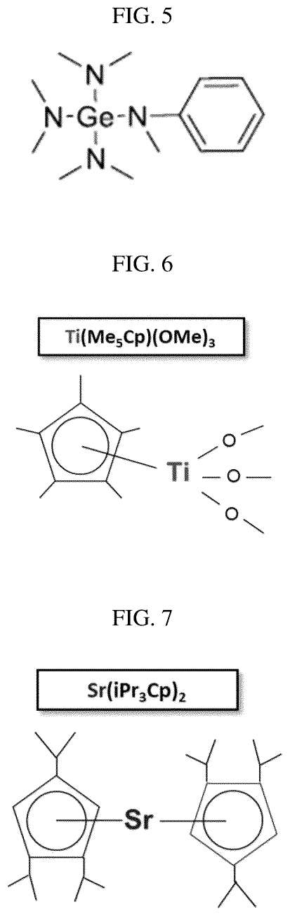

FIG. 5 is an exemplary drawing illustrating a Ge precursor that may be applied in a method of manufacturing a capacitor according to one embodiment of the present invention.

Referring to FIG. 5, in a method of manufacturing a capacitor according to an embodiment of the present invention, a Ge precursor comprising an amine group may be used. The Ge precursor may comprise an N atom bonded to a Ge atom. The Ge precursor may be Ge(NMePh)(NMe₂)₃. The Ge precursor may have high thermal stability as a precursor including an amine group, and may have high affinity with the material of the first electrode (e.g., Ru, etc.) because it includes a Ge atom and an N atom having a non-covalent electron pair within one molecular structure. According to an embodiment of the present invention, it may be possible to form a flat and well covered GeOₓ layer with only an initial one cycle in the first ALD process. However, the specific material of the Ge precursor is not limited to the foregoing, and may vary from case to case.

If the first electrode is a Ru electrode, a RuOₓ layer may be present on the surface of the Ru electrode as a natural oxide film. Further, a RuOₓ layer may also be formed on the surface of the Ru electrode by the first reactant supplied at the beginning of the first ALD process to form the buffer layer. In the first ALD process, the deposition of the Ge precursor from the RuOₓ layer may initially take place at a relatively high rate of about 2 to 2.5 Å/cycle due to the deprivation of oxygen by the Ge precursor, and the high surface energy of the first electrode may enable two-dimensional thin film growth.

FIG. 6 is an exemplary diagram illustrating a Ti precursor that may be applied in a method of manufacturing a capacitor according to one embodiment of the present invention.

FIG. 7 is a diagram illustrating an exemplary Sr precursor that may be applied in a method of manufacturing a capacitor according to one embodiment of the present invention.

Referring to FIGS. 6 and 7, a Cp (cyclopentadienyl)-based Ti precursor and a Cp-based Sr precursor may be used in the second ALD process. For example, the Ti precursor may be Ti(Me₅Cp)(OMe)₃, and the Sr precursor may be Sr(iPr₃Cp)₂. When the Cp-based Ti precursor and the Cp-based Sr precursor are used, the thin film properties of the dielectric layer may be improved at a deposition temperature of about 230° C. or higher. When deposition is performed at a low temperature below about 230° C., carbon or other ligands may be generated or retained, which may result in a degradation of the thin film properties. In this respect, it may be preferable to use a Cp-based Ti precursor and a Cp-based Sr precursor. However, the types of Ti precursors and Sr precursors are not limited to the foregoing. In some cases, other types of precursors other than those of the Cp series may be used.

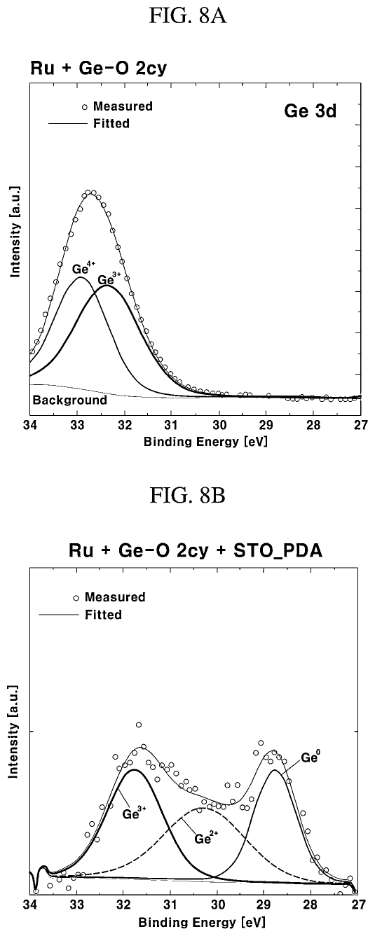

FIGS. 8A and 8B show graphs showing the results of an X-ray photoelectron spectroscopy (XPS) analysis of a buffer layer formed in a manufacturing method of a capacitor according to one embodiment of the present invention. FIGS. 8A and 8B show the results for Ge 3d. FIG. 8A shows the results for the buffer layer (GeOₓ layer) in the state of having formed the buffer layer (GeOₓ layer) on the Ru electrode (i.e., as-deposited state). FIG. 8B shows the results for the buffer layer (GeOₓ layer) and dielectric layer (strontium titanium oxide (STO) layer) formed on the Ru electrode, after post-deposition annealing (PDA) of the buffer layer and dielectric layer.

Referring to FIGS. 8A and 8B, the Ge 3d peak deconvolution data shows that some of the GeOₓ in the buffer layer has been reduced to Ge. In FIG. 8A, the entire buffer layer may be composed of GeOₓ and no peak corresponding to Ge⁰ appears. FIG. 8B shows a peak corresponding to Ge⁰, which may indicate that some of the GeOₓ has been reduced to Ge. During the deposition of GeOₓ, the Ge precursor may take away oxygen from the RuOₓ layer present on the surface of the Ru electrode, resulting in the oxide deposition of Geox, which has the strongest oxidizing power and thus reduces the content of RuOx, which is the oxygen source of STO. If Ti and Sr precursors with stronger oxygen binding capacity are subsequently fed, some of the Geox can be deprived of oxygen by the Ti and Sr precursors if certain process conditions are met. However, this phenomenon may not affect the initial overgrowth of STO, as the buffer layer has a lower reducing power compared to RuO₂, so the initial overgrowth of STOs may be maintained or even increased. The oxygen supply from GeOₓ to the dielectric layer (STO layer) can be at least by diffusion mechanism, and this oxygen supply can occur both during the deposition process of the dielectric layer (STO layer) and during the post-heat treatment process. Thus, the buffer layer after post-annealing may comprise GeOₓ regions and Ge regions (germanium material part).

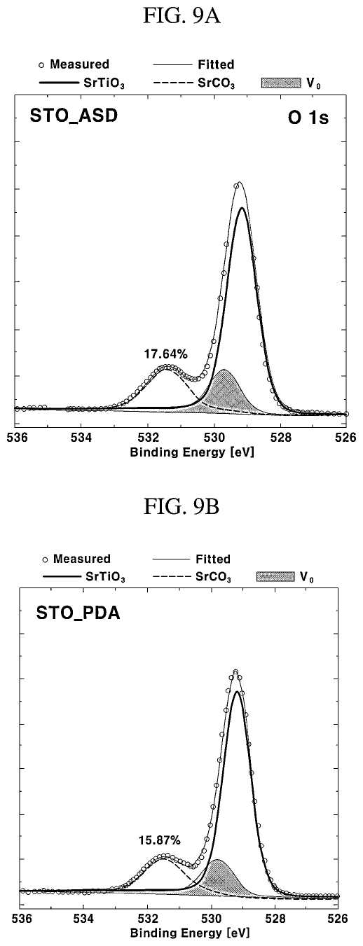

FIGS. 9A and 9B show graphs showing the results of XPS analysis of the dielectric layer formed in the capacitor fabrication method according to the comparison. FIGS. 9A and 9B show the results for O 1s. FIG. 9A is a result for the dielectric layer (STO layer) in the state in which the dielectric layer (STO layer) is formed without a buffer layer (i.e., as-deposited state). FIG. 9B is the result for the dielectric layer (STO layer) in the state of forming the dielectric layer (STO layer) without a buffer layer, and then performing a post-deposition annealing (PDA) on the dielectric layer.

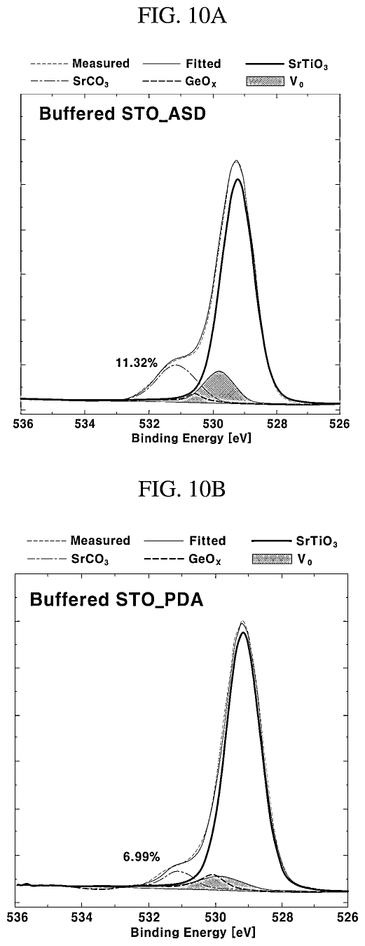

FIGS. 10A and 10B show graphs showing the results of an XPS analysis of a dielectric layer formed in a method of manufacturing a capacitor according to one embodiment of the present invention. FIGS. 10A and 10B show results for O 1s. FIG. 10A is the result for the dielectric layer (STO layer) in the state of having formed the dielectric layer (STO layer) on the buffer layer (i.e., as-deposited state). FIG. 10B is a result for the dielectric layer (STO layer) in a state in which the dielectric layer (STO layer) is formed on the buffer layer, and then a post-deposition treatment (PDA) is performed on the dielectric layer. In FIGS. 9A-10B, the region labeled V0 may correspond to the concentration of oxygen vacancies.

Referring to FIGS. 9A-10B, it can be seen that in the as-deposited state, the concentration of oxygen vacancies in the dielectric layer (STO layer) is significantly reduced (i.e., from 17.64 mol % to 11.32 mol %) by using the buffer layer according to the embodiment. Furthermore, it can be seen that the concentration of oxygen vacancies in the dielectric layer (STO layer) is further reduced (i.e., from 11.32 mol % to 6.99 mol %) during the post-depletion annealing (PDA) process. For example, the dielectric layer (STO layer) prepared according to an embodiment of the present invention may have an oxygen vacancy concentration of about 10 mol % or less after the heat treatment process. The lower the oxygen vacancy concentration, the better the crystalline properties of the strontium titanium oxide may be, and the better the dielectric properties and electrical properties may be. However, the oxygen vacancy concentration of the dielectric layer (STO layer) is not limited to the foregoing, and may vary in some cases.

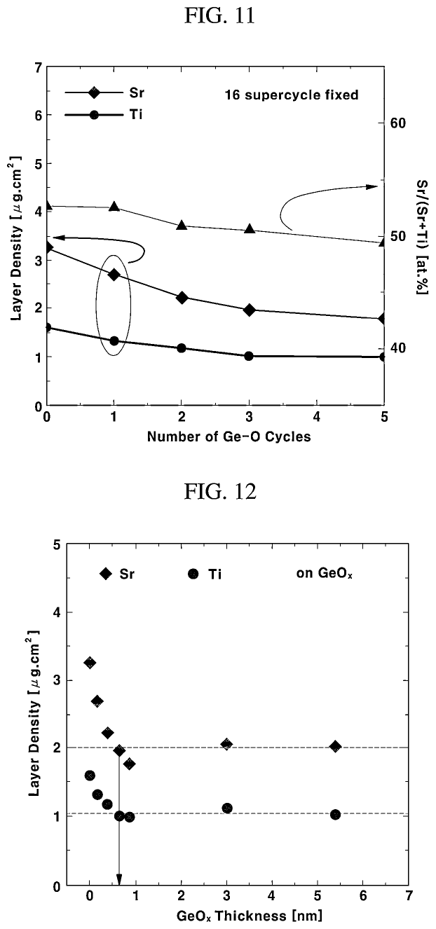

FIG. 11 is a graph showing the variation of the layer density of Sr and Ti in the STO layer as a function of the number of ALD cycles of GeOₓ (i.e., Ge—O) corresponding to the buffer layer, for a fixed number of strontium titanium oxide (STO) cycles, in a method of manufacturing a capacitor according to one embodiment of the present invention. The layer density of Sr and Ti can mean the adsorption amount of Sr atoms and Ti atoms per unit area of the STO thin film, respectively.

FIG. 12 is a graph showing the variation of the layer density of Sr and Ti in the STO layer as a function of the thickness of the GeOₓ layer corresponding to the buffer layer, for a fixed number of strontium titanium oxide (STO) cycles, in a method of manufacturing a capacitor according to one embodiment of the present invention.

Referring to FIGS. 11 and 12, it can be seen that, compared to when no Ge—O cycle is inserted, even if only one cycle of Ge—O is inserted, the adsorption amount (deposition amount) of the constituents of STO, especially Sr, which has a stronger reducing power, is significantly reduced, and excessive deposition is suppressed. Furthermore, it can be seen that the adsorption amount (deposition amount) of Sr and Ti is saturated at a thickness of the buffer layer (GeOₓ layer) of about 0.7 nm, and sufficient oxygen barrier effect by the buffer layer is shown. In embodiments of the present invention, it may be advantageous to reduce the thickness of the GeOₓ layer having a relatively low dielectric constant as much as possible while securing a certain degree of oxygen barrier effect. In this regard, as a non-limiting example, the number of ALD cycles for the formation of the GeOₓ layer may be on the order of one, two, or more than two cycles.

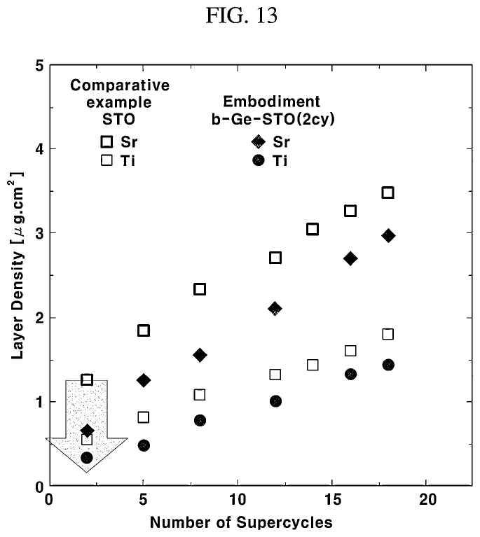

FIG. 13 is a graph showing the change in the layer density of Sr and Ti in the STO layer as a function of the number of super cycles of strontium titanium oxide (STO) in the manufacturing method of the capacitor according to an embodiment and a comparative example of the present invention. Here, the above embodiment is a case where 2 cycles of GeOₓ layer are applied as a buffer layer, and the above comparative example is a case where no buffer layer is applied.

Referring to FIG. 13, the evolution of the deposition amount with the number of super-cycles of STO in the embodiment with 2 cycles of GeOₓ layer applied as a buffer layer shows that the deposition amount within the first few cycles is significantly reduced compared to the case without the buffer layer, effectively blocking the initial over-adsorption phenomenon.

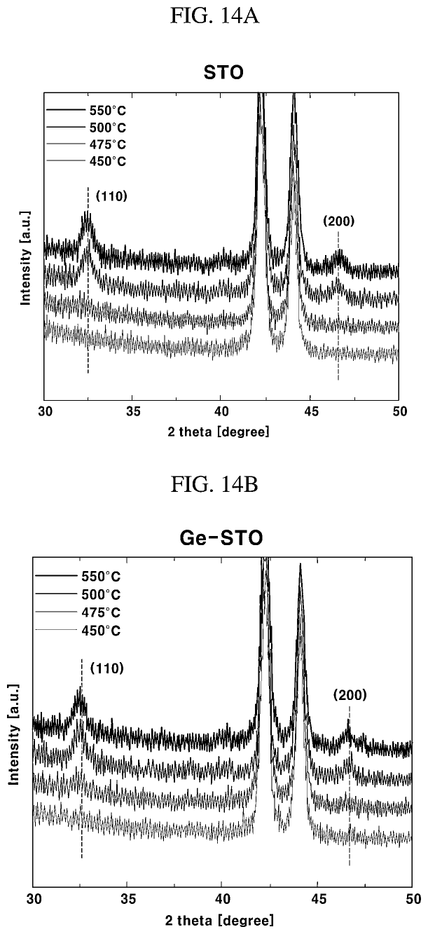

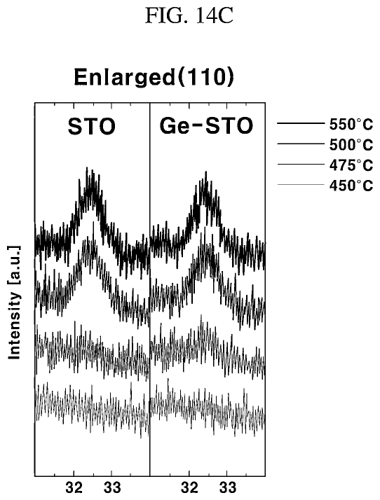

FIGS. 14A-14C show grazing incident X-ray diffraction (GIXRD) analysis graphs showing the crystallization behavior of the dielectric layer as a function of the post-heat treatment temperature of the dielectric layer according to an embodiment of the present invention and a comparative example. FIG. 14A is a result for a dielectric layer according to a comparative example, wherein the dielectric layer according to the comparative example is a pristine STO layer. FIG. 14B is the result for a dielectric layer according to an embodiment, wherein the dielectric layer according to the embodiment is an STO layer formed on a buffer layer comprising GeOₓ. FIG. 14C shows a zoomed-in view of the main areas of the FIGS. 14A-14B.

Referring to FIGS. 14A-14C, it can be seen that both the dielectric layer according to the embodiment and the comparative example are in an amorphous state at a post-heat treatment temperature of 450° C. or lower, but only the dielectric layer according to the embodiment has a crystallization peak detected at a post-heat treatment temperature of 475° C. Therefore, when the buffer layer according to an embodiment of the present invention is applied, the crystallization temperature of the dielectric layer can be lowered. In other words, low-temperature crystallization of the dielectric layer can be facilitated by the buffer layer according to an embodiment of the present invention.

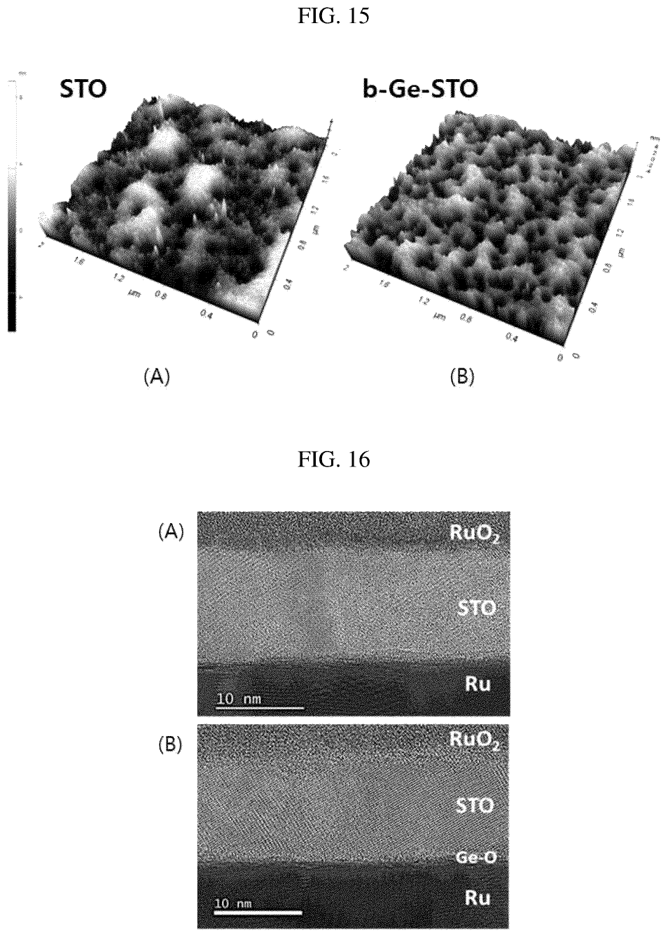

FIG. 15 is a diagram illustrating atomic force microscope (AFM) analysis images (three-dimensional images) of a dielectric layer according to an embodiment of the present disclosure and a comparative example. Graph (A) in FIG. 15 is a result for a dielectric layer according to a comparative example, wherein the dielectric layer according to the comparative example is a pristine STO layer. The (B) graph in FIG. 15 is the result for a dielectric layer according to an embodiment, wherein the dielectric layer according to the embodiment is an STO layer formed on a buffer layer comprising GeOₓ. Both the dielectric layer according to the above embodiments and the comparative example were post-treated to 475° C.

Referring to FIG. 15, it can be seen that when both the dielectric layer according to the above embodiment and the comparative example are post-heat treated to 475° C., the dielectric layer according to the above embodiment shows higher nuclei density. This may be a result of the nucleation of the dielectric layer (STO layer) being promoted by the buffer layer according to an embodiment of the present invention.

FIG. 16 is a high resolution transmission electron microscope (HRTEM) image showing a cross section of a dielectric layer in accordance with embodiments and comparative examples of the present invention.

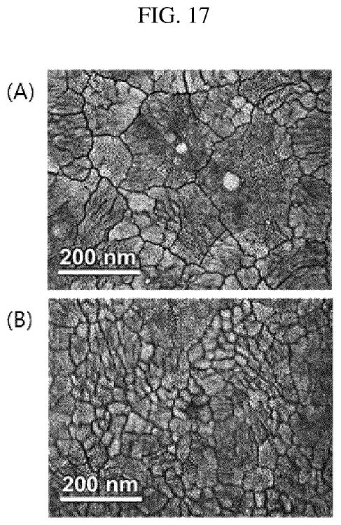

FIG. 17 is a scanning electron microscope (SEM) image showing the surface of a dielectric layer according to embodiments and comparative examples of the present invention.

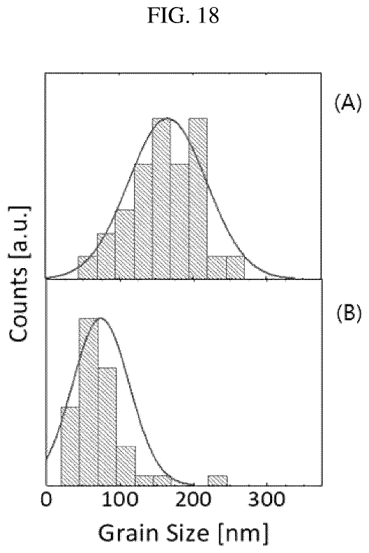

FIG. 18 is a graph showing the grain size distribution of a dielectric layer according to embodiments and comparative examples of the present invention.

In FIGS. 16 through 18, (A) is a result for a dielectric layer according to a comparative example, wherein the dielectric layer according to the comparative example is an STO layer formed without a buffer layer. In FIGS. 16 through 18, (B) is a result for a dielectric layer according to an embodiment, wherein the dielectric layer according to the embodiment is an STO layer formed on a buffer layer comprising Geox. The dielectric layers according to the above embodiments and comparative examples were all post-treated at a temperature of 650° C. to sufficiently crystallize.

Referring to FIGS. 16 through 18, a comparison of the grain size of the dielectric layer of the exemplary and comparative embodiments shows that the grain size is smaller in the dielectric layer of the exemplary embodiment with a faster initial stage of nucleation. However, the results of FIGS. 16 through 18 are exemplary and relative, and the average size and size distribution of grains in the dielectric layer of the embodiments may vary depending on process conditions and the like.

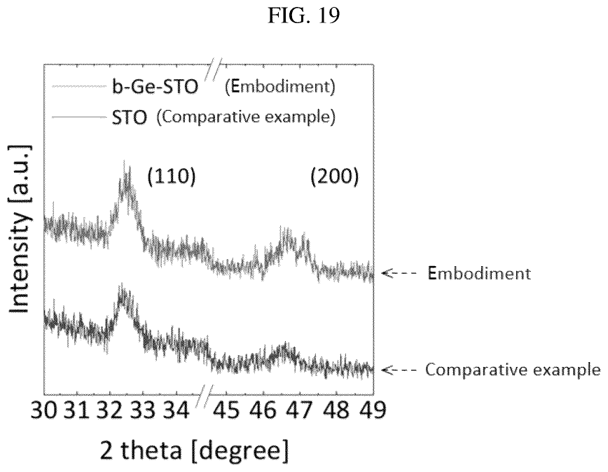

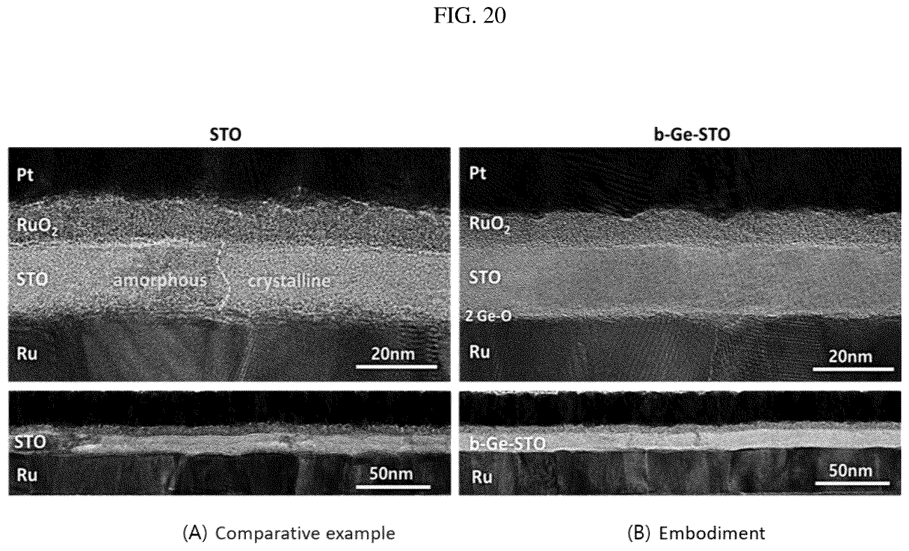

FIG. 19 is a graph showing the results of a GIXRD analysis of a dielectric layer according to embodiments and comparative examples of the present invention.

FIG. 20 is an HRTEM image showing a cross-section of a dielectric layer according to an embodiment and comparative example of the present invention.

In FIGS. 19 and 20, the dielectric layer according to the comparative example is an STO layer formed without a buffer layer, and the dielectric layer according to the embodiment is an STO layer formed on a buffer layer comprising GeOₓ. The dielectric layers according to the above embodiments and comparative examples were all post-treated at a temperature of 575° C. The dielectric layers according to the embodiments may show an initial stage of nucleation at an annealing temperature of about 450 to 475° C., and at an annealing temperature of 600° C. or higher, both dielectric layers may crystallize as a whole. Therefore, at a post-heat treatment temperature of 575° C., which is a temperature between 475° C. and 600° C., it was determined whether there is a significant difference in the crystallinity of the dielectric layer according to the Exemplary and Comparative Examples.

Referring to FIGS. 19 and 20, it can be seen that there is a significant difference in the crystallinity of the dielectric layer according to the embodiment and the comparative example at a post-annealing temperature of 575° C. It can be seen that the dielectric layer (STO layer) according to the embodiment is well crystallized throughout the thin film, while the dielectric layer (STO layer) according to the comparative example has mixed amorphous and crystalline regions.

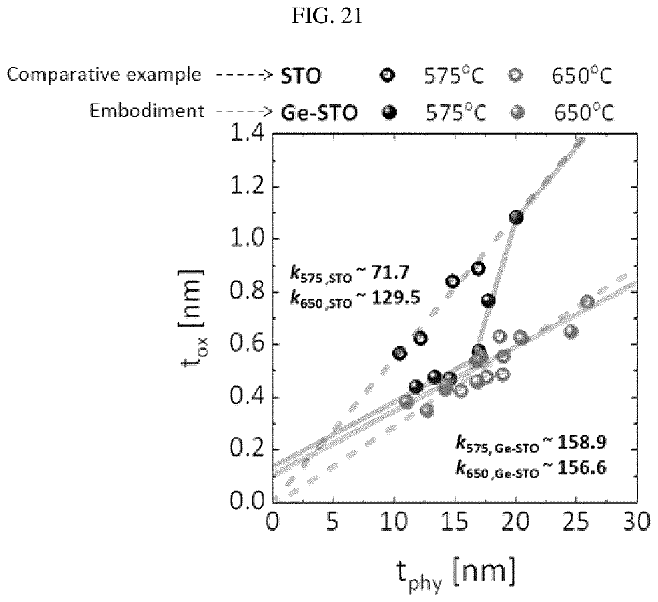

FIG. 21 is a graph showing the variation of the equivalent oxide thickness (tₒₓ) with the physical oxide thickness (t_{phy}) of a dielectric layer prepared according to an embodiment and a comparative example of the present invention. In FIG. 21, the dielectric layer according to the comparative example is an STO layer formed without a buffer layer, and the dielectric layer according to the embodiment is an STO layer formed on a buffer layer comprising GeOₓ. Both the dielectric layer according to the embodiment and the comparative example were post-treated at a temperature of 575° C. and 650° C.

Referring to FIG. 21, in the dielectric layer according to the embodiment, a high dielectric constant of about 158.9 was obtained even at a post-heat treatment of 575° C., which is comparable to that at a post-heat treatment of 650° C. On the other hand, the dielectric layer according to the comparative example exhibited a low dielectric constant of about 71.7 at a post-heat treatment of 575° C. Thus, it can be seen that the dielectric layer according to the embodiment can obtain excellent dielectric properties even at a relatively low post-heat treatment temperature. Furthermore, in the case of the dielectric layer according to the embodiment, since the ALD cycle of the lower buffer layer (GeOₓ) is fixed, it can be seen that the EOT (tₒₓ) increases without being affected by the lower layer above a certain physical thickness (about 17 nm).

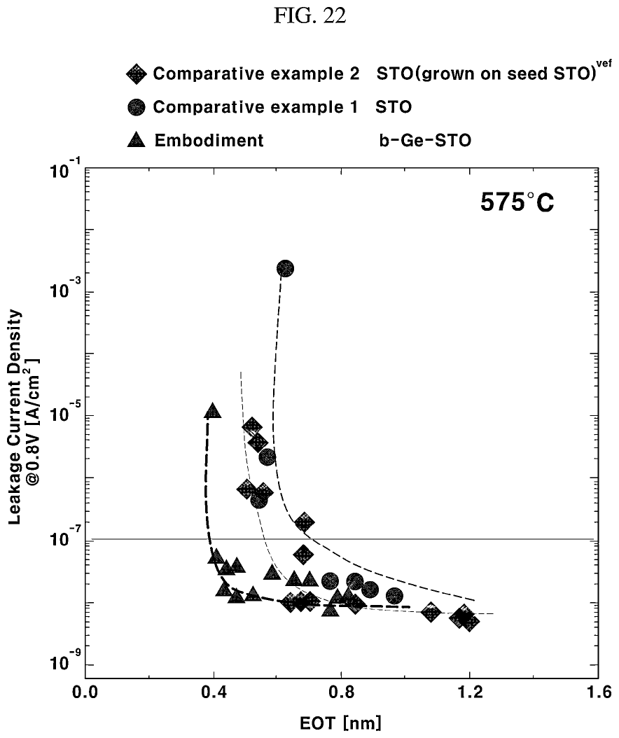

FIG. 22 is a graph showing the variation of leakage current density with equivalent oxide thickness (EOT) of dielectric layers fabricated according to embodiments and comparative examples of the present invention. In FIG. 22, the dielectric layer according to the first comparative example is an STO layer formed without a buffer layer, the dielectric layer according to the second comparative example is an STO layer formed on a seed STO layer using a two-step process, and the dielectric layer according to the embodiment is an STO layer formed on a buffer layer comprising GeOₓ. The dielectric layers according to the above embodiments and comparative examples were all post-treated to a temperature of 575° C.

Referring to FIG. 22, upon post-heat treatment at 575° C., the J-EOT characteristic was improved by reducing the EOT due to an increase in the crystallinity of the dielectric layer according to the embodiment, and STO thin film satisfying the leakage current requirement for DRAM capacitors was obtained even though the entire dielectric layer was heat treated without using a seed layer. The minimum EOT that satisfies the leakage current criteria for DRAM capacitors was 0.43 nm, and the physical oxide thickness (POT) was 11.8 nm. However, these thickness figures and related characteristics are only exemplary and may vary depending on process conditions, etc.

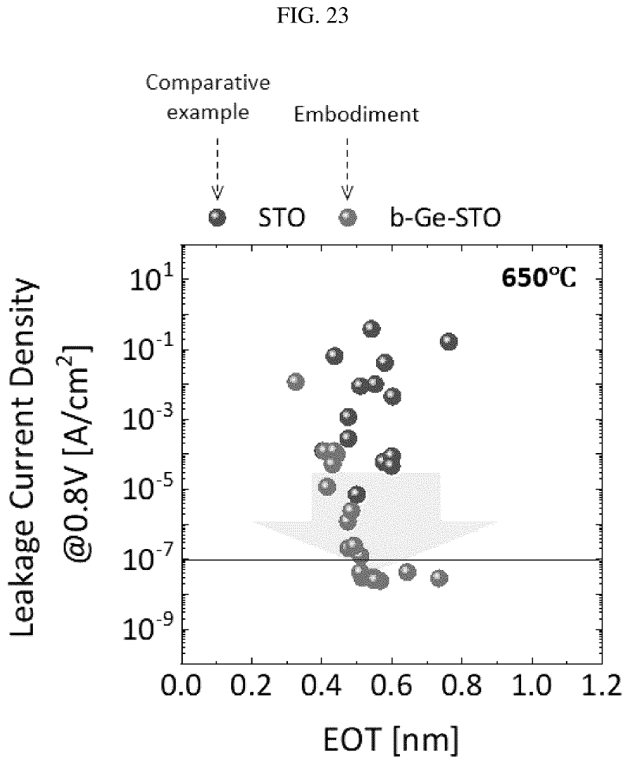

FIG. 23 is a graph showing the variation of leakage current density with equivalent oxide thickness (EOT) of dielectric layers fabricated according to embodiments and comparative examples of the present invention. In FIG. 23, the dielectric layer according to the comparative example is an STO layer formed without a buffer layer, and the dielectric layer according to the embodiment is an STO layer formed on a buffer layer comprising GeOₓ. Both the dielectric layer according to the embodiment and the comparative example were post-treated at a temperature of 650° C.

Referring to FIG. 23, it can be seen that the dielectric layer according to the embodiment has lower leakage current characteristics than the dielectric layer according to the comparative example.

The capacitors according to embodiments of the present invention can be applied to various semiconductor devices. For example, a capacitor according to an embodiment of the present invention may be applied to a memory device that utilizes a capacitor as a data storage member. Here, the memory device may be a dynamic random access memory (DRAM). In order to apply the capacitor to DRAM, it may be desirable to manufacture the capacitor by an ALD process. Since the capacitors according to embodiments of the present invention can be fabricated by an ALD process, they can be easily applied to highly integrated DRAMs. Although FIGS. 1 and 3 illustrate a capacitor with a simple structure, when applied as a capacitor for DRAM, the capacitor according to an embodiment of the present invention can have various three-dimensional structures, such as a cylinder shape, a cup shape, and the like.

A DRAM device to which a capacitor according to one embodiment of the present invention may be applied may include a cell transistor and a capacitor electrically coupled thereto. The capacitor structures and manufacturing methods according to embodiments of the present invention described in FIG. 1 and FIGS. 2a through 2e may be applied to the DRAM capacitor. When a capacitor according to an embodiment of the present invention is applied to a DRAM, it may be advantageous in improving integration and improving performance. Furthermore, the capacitors according to embodiments of the present invention can be applied to other memory devices other than DRAMs and other semiconductor devices.

According to the embodiments of the present invention described above, a capacitor and a manufacturing method thereof capable of reducing leakage current while having a high capacitance characteristic can be realized. Furthermore, according to embodiments of the present invention, a capacitor and a manufacturing method thereof can be implemented that can improve electrical properties by suppressing over-deposition (over-growth) of dielectric layers and promoting low-temperature crystallization. Furthermore, according to embodiments of the present invention, capacitors and methods of manufacturing the same can be implemented that can reduce the thermal budget and thermal process burden by reducing the heat treatment temperature and simplify the dielectric layer formation process.

In particular, according to embodiments of the present invention, by inserting a predetermined buffer layer between the first electrode and the dielectric layer, the CVD-like (i.e., CVD-like) overgrowth of the strontium titanium oxide in the dielectric layer can be effectively suppressed at the beginning of the deposition. Furthermore, as the buffer layer promotes the early stage of nucleation of strontium titanium oxide, crystallization can be achieved at a relatively low temperature, and the leakage current density versus equivalent oxide thickness characteristics, i.e., J-EOT characteristics, can be improved. By reducing the complexity of the dielectric layer formation process, the application of strontium titanium oxide as a DRAM capacitor can be improved by using a one-step process based on an in-situ process rather than a conventional two-step process. Furthermore, by reducing the heat treatment temperature, the thermal cost and thermal process burden of the DRAM capacitor process can be reduced.

The capacitors according to embodiments of the present invention can be usefully applied to various devices. In particular, the capacitor according to an embodiment of the present invention may be applied to a semiconductor device, for example, a memory device such as a DRAM, in which case it may be advantageous to improve the integration and performance of the memory device.

This description discloses preferred embodiments of the present invention, and although certain terms are used, they are used in a general sense only to facilitate the description and understanding of the invention and are not intended to limit the scope of the invention. In addition to the embodiments disclosed herein, other modifications based on the technical ideas of the present invention will be apparent to those of ordinary skill in the art to which the present invention belongs. One having ordinary knowledge in the art will recognize that the capacitor according to the embodiments described with reference to FIGS. 1 to 23, the method of making the capacitor, and the device comprising the capacitor, may be variously substituted, altered, and modified without departing from the technical idea of the invention. The scope of the invention is therefore not to be defined by the embodiments described, but by the technical idea recited in the patent claims.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A capacitor comprising:
a first electrode;
a second electrode disposed spaced apart from the first electrode;
a dielectric layer disposed between the first electrode and the second electrode, comprising strontium titanate oxide; and
s capacitor disposed between the first electrode and the dielectric layer, comprising a germanium oxide and a germanium material portion, the germanium material portion comprising a buffer layer comprising oxygen and uncombined germanium.

2. The capacitor of claim 1, wherein the germanium oxide is a capacitor with Geox (where x is 0<x≤2).

3. The capacitor of claim 1, wherein the content of the germanium material portion in the buffer layer is less than 50 wt %.

4. The capacitor of claim 1, wherein the buffer layer has a thickness in the range of 0.2 nm to 3 nm.

5. The capacitor of claim 1, wherein the strontium titanium oxide is SrₓTi₁₋ₓO_{3-y} (wherein x is 0.45≤x≤0.55 and y is 0≤y≤0.5).

6. The capacitor of claim 1, wherein an oxygen vacancy concentration of the strontium titanium oxide is equal or less than 20 mol %.

7. The capacitor of claim 1, wherein the dielectric layer has a thickness in the range of 1 nm to 30 nm.

8. The capacitor of claim 1, wherein the first electrode includes at least one of Ru and RuOₓ (wherein x is 0<x≤2).

9. The capacitor of claim 1, wherein the second electrode includes at least one of RuOₓ (wherein x is 0<x≤2), Ru, Pt, and TiN.

10. A memory device comprising the capacitor of claim 1 as a data storage member.

11. A method of manufacturing a capacitor, comprising:
prepare a first electrode;
forming a buffer layer comprising germanium oxide on the first electrode using a first atomic layer deposition (ALD) process;
forming a dielectric layer comprising strontium titanate oxide on the buffer layer using a second ALD process; and
forming a second electrode on the dielectric layer,
wherein the buffer layer and the dielectric layer are heat treated by a heat treatment process, and
after the heat treatment process, wherein the buffer layer comprises a germanium oxide and a germanium material portion, and the germanium material portion comprises germanium uncombined with oxygen.

12. The method of claim 11, wherein the first ALD process comprises,
supplying a Ge precursor to a chamber in which the first electrode is disposed;
purging the chamber with a first purge gas;
supplying a first reactant into the chamber; and
purging the chamber with a second purge gas.

13. The method of claim 11, wherein the second ALD process comprises a first sub-cycle and a second sub-cycle,
wherein the first sub-cycle comprises,
supplying a Ti precursor to a chamber in which the first electrode with the buffer layer formed is disposed;
purging the chamber with a third purge gas;
supplying a second reactant into the chamber; and
purging the chamber with a fourth purge gas,
wherein the second sub-cycle comprises,
feeding a Sr precursor into the chamber;
purging the chamber with a fifth purge gas;
supplying a third reactant into the chamber; and
purging the chamber with a sixth purge gas.

14. The method of claim 11, wherein a deposition temperature of a method of forming a buffer layer and forming a dielectric layer, respectively, ranges from 230 to 370° C.

15. The method of claim 11, wherein the heat treatment process is performed at a temperature of 450 to 700° C.

16. The method of claim 11, after the heat treatment process, wherein the germanium oxide contained in the buffer layer is GeOₓ (wherein x is 0<x≤2), and the content of the germanium material portion in the buffer layer is less than 50 wt %.

17. The method of claim 11, after the heat treatment process, wherein the oxygen vacancy concentration of the strontium titanate oxide is equal to or less than 20 mol %.

18. The method of claim 11, wherein the first electrode comprises at least one of Ru and RuOₓ (wherein x is 0<x≤2), and the second electrode comprises at least one of RuOₓ (wherein x is 0<x≤2), Ru, Pt, and TiN.
